(19) United States
(12) Patent Application Publication
(10) Pub. No.: US 2026/0101528 A1
(43) Pub. Date: Apr. 9, 2026

(54) MEMORY DEVICE AND MANUFACTURING METHOD THEREOF

(71) Applicant: Winbond Electronics Corp., Taichung City (TW)

(72) Inventor: Huang-Nan Chen, Taichung City (TW)

(73) Assignee: Winbond Electronics Corp., Taichung City (TW)

(21) Appl. No.: 19/258,914

(22) Filed: Jul. 3, 2025

(30) Foreign Application Priority Data
Oct. 7, 2024 (TW) 113138082

(51) Int. Cl. H10D 1/68; H10B 12/00; H10D 1/00

(52) U.S. Cl. CPC H10D 1/696; H10B 12/033; H10B 12/31; H10B 12/482; H10B 12/485; H10D 1/042; H10D 1/043; H10D 1/716

(57) ABSTRACT

A memory device and a manufacturing method thereof are provided. The memory device includes: an access transistor; and a capacitor contact structure configured to connect a source/drain of the access transistor to an overlying storage capacitor, and including: a bottom contact structure; and a top contact structure disposed above the bottom contact structure and including a barrier layer and a conductive filler material connected to the bottom contact structure via the barrier layer. The barrier layer is extended along a bottom portion and two opposite sidewalls of the conductive filler material. A lower portion of the conductive filler material is filled in a recess defined by the barrier layer, and an upper portion of the conductive filler material is higher than a topmost end of the barrier layer and has a greater width relative to the lower portion of the conductive filler material.

### CROSS-REFERENCE TO RELATED APPLICATION

This application claims the priority benefit of Taiwan application serial no. 113138082, filed on October 7, 2024. The entirety of the above-mentioned patent application is hereby incorporated by reference herein and made a part of this specification.

### BACKGROUND OF THE INVENTION

### Field of the Invention

The invention relates to a semiconductor device and a manufacturing method thereof, and in particular, to a memory device and a manufacturing method thereof.

### Description of Related Art

With the development of dynamic random-access memory (DRAM) manufacturing processes, the volume density of DRAM continues to increase. This allows DRAM to store a greater amount of data in a given area. However, with the increase in storage density and the drastic miniaturization of DRAM cells, the capacitive contact structure used to connect the access transistor and the storage capacitor in each DRAM cell is significantly reduced in size. Due to being limited to a relatively small size, holes are readily generated in the capacitive contact structure, and the holes may be extended to the surface of the capacitive contact structure. As a result, electrical connection between the access transistor and the storage capacitor may not be facilitated, thus affecting the operating performance of the DRAM.

### SUMMARY OF THE INVENTION

The disclosure provides a memory device and a manufacturing method thereof that may maintain or even improve the electrical connection between an access transistor and a storage capacitor while pursuing miniaturization of the memory device.

According to some embodiments of the disclosure, a memory device includes: an access transistor; a capacitive contact structure configured to connect a drain/source of the access transistor to an overlying storage capacitor, and including: a bottom contact structure; and a top contact structure disposed above the bottom contact structure and including a barrier layer and a conductor filler material connected to the bottom contact structure via the barrier layer, wherein the barrier layer is extended along a bottom surface and two opposite sidewalls of the conductor filler material, a lower portion of the conductor filler material is filled in a recess defined by the barrier layer, and an upper portion of the conductor filler material is higher than a topmost end of the barrier layer and has a greater width relative to the lower portion; and a bit line stack structure adjacent to the capacitive contact structure and having a bit line connected to another drain/source of the access transistor.

According to some embodiments of the disclosure, a manufacturing method of a memory device includes: forming a plurality of access transistors in a substrate; forming a bit line stack structure on the substrate, wherein the bit line stack structure crosses over a plurality in the plurality of access transistors; and forming a plurality of capacitive contact structures on the substrate along two sides of the bit line stack structure, wherein the plurality of capacitive contact structures respectively include: a bottom contact structure; and a top contact structure disposed above the bottom contact structure and including a barrier layer and a conductor filler material connected to the bottom contact structure via the barrier layer, wherein the barrier layer is extended along a bottom surface and two opposite sidewalls of the conductor filler material, a lower portion of the conductor filler material is filled in a recess defined by the barrier layer, and an upper portion of the conductor filler material is higher than a topmost end of the barrier layer and has a greater width relative to the lower portion.

### BRIEF DESCRIPTION OF THE DRAWINGS

FIG. 1A is a schematic plan view of a memory device according to some embodiments of the disclosure.

FIG. 1B is a schematic cross-sectional view shown along line X-X’ of FIG. 1A.

FIG. 1C is a schematic cross-sectional view shown along line Y-Y’ of FIG. 1A.

FIG. 1D is a three-dimensional schematic view showing a plurality of memory cells disposed along a bit line.

FIG. 2 is a flowchart of a method for forming a memory device according to some embodiments.

FIG. 3A to FIG. 3G are schematic three-dimensional views of a series of intermediate structures during the manufacturing process shown in FIG. 2.

FIG. 4A to FIG. 4G show a patterning operation for forming a capacitive contact structure of some embodiments using schematic cross-sectional views in a second direction.

### DESCRIPTION OF THE EMBODIMENTS

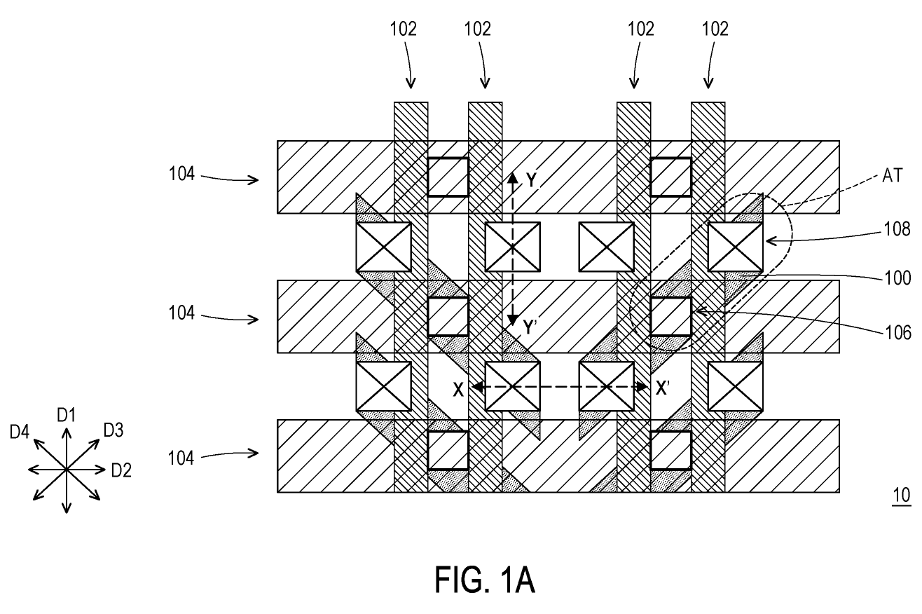

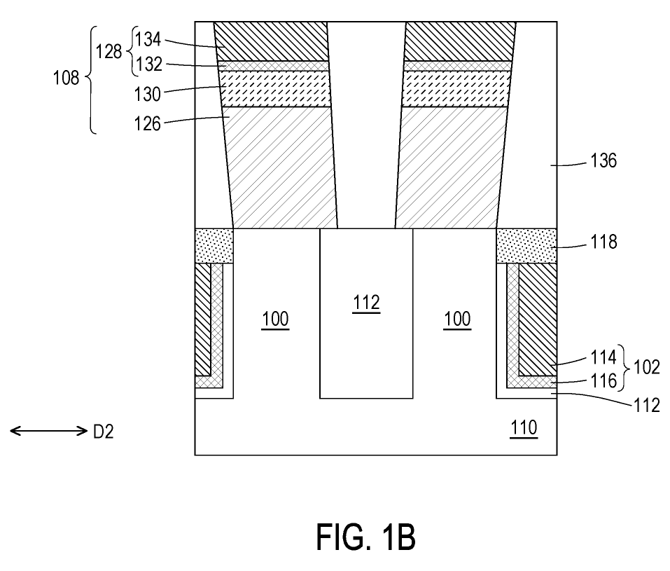

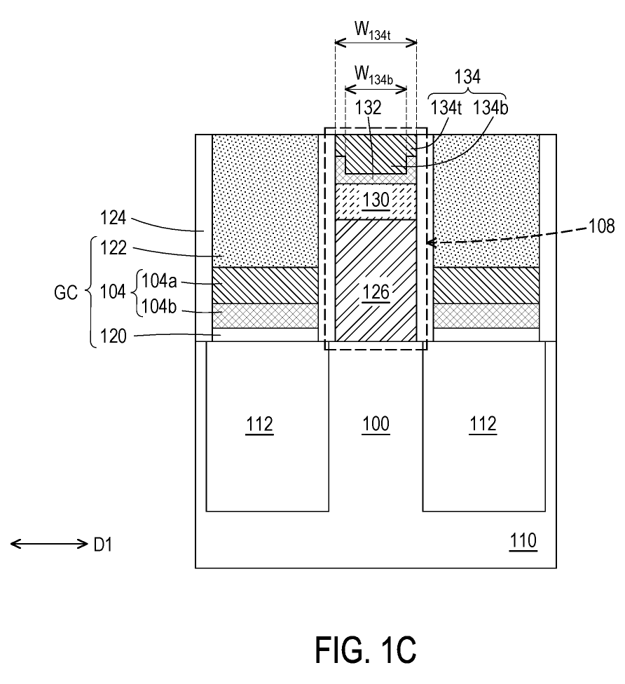

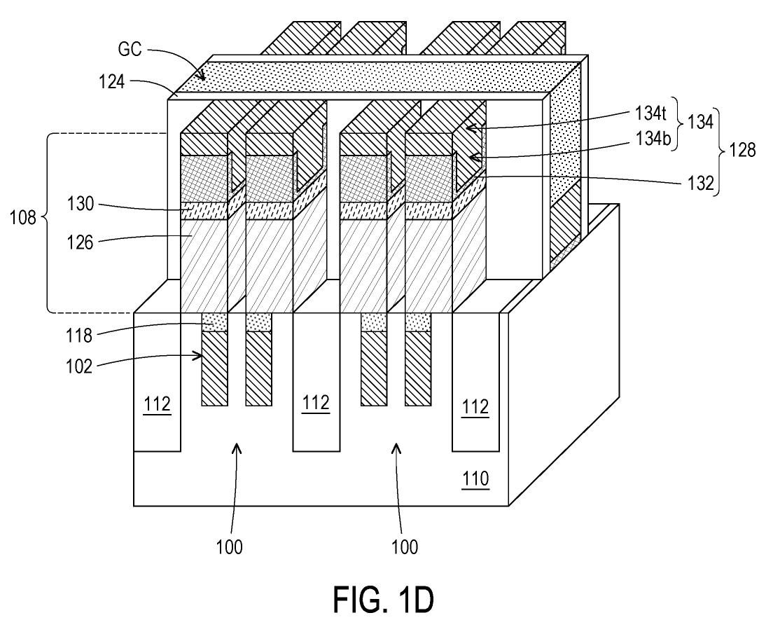

FIG. 1A is a schematic plan view of a memory device 10 according to some embodiments of the disclosure. Referring to FIG. 1A, a memory device 10 as a dynamic random-access memory (DRAM) includes a plurality of active areas 100 arranged along a first direction D1 and a second direction D2 staggered with the first direction D1. As will be explained below with reference to FIG. 1B to FIG. 1D, the active areas 100 may be a plurality of portions of a substrate separated by isolation structures. In some embodiments, extension directions D3 and D4 of the active areas 100 are staggered with the first direction D1 and the second direction D2. In such embodiments, the active area 100 of each column may be extended along one of the directions D3 and D4, and the active areas 100 of adjacent columns are extended along the other of the directions D3 and D4. In this way, the active areas 100 of two adjacent columns are symmetrical with respect to the central axis between each other.

A plurality of word lines 102 are extended along the first direction D1 and pass through each of the active areas 100. Access transistors AT of the memory cells are respectively defined in the staggered areas of an active area 100 and a word line 102. For each of the access transistors AT, the word line 102 that the access transistor AT passes through serves as a gate, and the portions of the active areas 100 located at two opposite sides of the word line 102 that the portions of the active areas 100 pass through serve as drains and sources. In some embodiments, each of the active areas 100 is crossed by two word lines 102 and shared by two access transistors AT. In such embodiments, the portion of each of the active areas 100 located between two passing word lines 102 may serve as the common source/drain of the two shared access transistors AT.

A plurality of bit lines 104 are extended along the second direction D2 and crosses over each of the active areas 100. One of the source/drain of each of the access transistors AT is connected to the staggered bit line 104 via a bit line contact structure 106. In an embodiment in which each of the active areas 100 is shared by two access transistors AT, the bit lines 104 are connected to the common source/drain portion of each of the active areas 100 via the bit line contact structure 106.

The other source/drain of each of the access transistors AT is connected to the overlying storage capacitor (not shown) via a capacitive contact structure 108. In this way, one source/drain of each of the access transistors AT is connected to a bit line 104, and the other source/drain is connected to the storage capacitor. In an embodiment in which each of the active areas 100 is shared by two access transistors AT, the portions of each of the active areas 100 located at two opposite sides of the two passing word lines 102 and serving as non-common source/drain are connected to corresponding storage capacitors via two capacitor contact structures 108.

FIG. 1B is a schematic cross-sectional view shown along line X-X’ of FIG. 1A, and FIG. 1C is a schematic cross-sectional view shown along line Y-Y’ of FIG. 1A. Moreover, FIG. 1D is a three-dimensional schematic view showing a plurality of memory cells disposed along a bit line 104.

As shown in FIG. 1B to FIG. 1D, the active areas 100 are some portions of the substrate 110 and respectively surrounded by isolation structures 112 and laterally spaced apart from each other. In addition, as shown in FIG. 1B, the word lines 102 are embedded in the substrate 110 to laterally penetrate the active areas 100 and the isolation structures 112. Each of the word lines 102 includes a gate conductor structure 114 and a gate dielectric layer 116 covering the sidewalls and the bottom surface of the gate conductor structure 114. In some embodiments, the word lines 102 are buried deeply into the substrate 110 such that the top surface of the word lines 102 is lower than the topmost surface of the substrate 110. In such embodiments, an insulating plug 118 may be filled in the substrate 110 to cover the top surface of the word lines 102. As an example, the material of the insulating plug 118 may include silicon nitride, silicon oxide (tetraethoxysilane (TEOS), spin on glass (SOG), the like, or a combination thereof) or a combination thereof.

As shown in FIG. 1C, the bit lines 104 are disposed above the substrate 110. In some embodiments, the bit lines 104 include a first conductor layer 104a and a second conductor layer 104b extended along the bottom surface of the first conductor layer 104a. As an example, the first conductor layer 104a includes tungsten, and the second conductor layer 104b includes titanium and titanium nitride. Additionally, in some embodiments, an insulating layer 120 is disposed between the bit lines 104 and the substrate 110. In addition, in some embodiments, one or a plurality of insulating layers 122 are stacked above the bit lines 104. The sidewalls of the insulating layer 122 may be substantially flush with the sidewalls of the bit lines 104 and/or the sidewalls of the insulating layer 120. For illustrative purposes, each of the bit lines 104 and the insulating layers 120 and 122 below and above the bit lines 104 are also referred to herein as a bit line stack structure GC.

In some embodiments, spacers 124 formed by an insulating material are disposed along the sidewalls of the bit line stack structure GC to ensure that the bit lines 104 may be appropriately electrically isolated from surrounding conductor structures. For example, as shown in FIG. 1C and FIG. 1D, the bit line stack structure GC is appropriately separated from the capacitive contact structure 108 via the spacers 124. As an example, the insulating material 124 may include silicon nitride, silicon oxide (tetraethoxysilane (TEOS), spin on glass (SOG), the like, or a combination thereof) or a combination thereof.

As shown in FIG. 1B to FIG. 1D, the capacitive contact structure 108 is in contact with the active areas 100 from above the substrate 110. It may be seen from FIG. 1C and FIG. 1D that the capacitive contact structure 108 is adjacent to the bit line stack structure GC and arranged along each of the bit line stack structures GC. Each of the capacitive contact structures 108 includes a bottom contact structure 126 in contact with the active areas 100 and a top contact structure 128 stacked above the bottom contact structure 126 and in contact with a storage capacitor (not shown). In some embodiments, the bottom contact structure 126 is formed by a conductive material such as polysilicon. In an example in which the bottom contact structure 126 is formed by polysilicon, the bottom contact structure 126 may be in contact with the top contact structure 128 via the metal silicide layer 130. Moreover, the top contact structure 128 includes a barrier layer 132 and a conductor filler material 134. The conductor filler material 134 is in contact with the bottom contact structure 126 via the barrier layer 132. In some embodiments, the conductor filler material 134 is formed by a conductive material, such as tungsten, and the barrier layer 132 is formed by a conductive material including, for example, titanium and titanium nitride.

The conductor filler material 134 has a lower portion 134b and an upper portion 134t. The lower portion 134b is filled in the recess defined by the barrier layer 132. Specifically, the barrier layer 132 is extended along the bottom surface of the lower portion 134b of the conductive filler material 134, and further extended to the sidewalls of the lower portion 134b. As a result of the specific process sequence, the barrier layer 132 does not entirely laterally surround the lower portion 134b of the conductor filler material 134, but only covers two of the sidewalls of the lower portion 134b. As shown in FIG. 1D, the barrier layer 132 only covers two opposite sidewalls of the lower portion 134b of the conductor filler material 134 substantially parallel to the bit line stack structure GC, and does not cover the other two sidewalls of the lower portion 134b substantially perpendicular to the bit line stack structure GC.

Due to being confined within the recess defined by the barrier layer 132, the lower portion 134b of the conductor filler material 134 may generate cavities or holes during the forming process. Nonetheless, the lower portion 134b of the conductor filler material 134 is then covered by the upper portion 134t. Compared with the lower portion 134b, the upper portion 134t is not limited to the recess of the barrier layer 132 and has a greater width (that is, a width W₁₃₄ₜ of the upper portion 134t is greater than a width W_{134b} of the lower portion 134b). In this way, the upper portion 134t is less likely to form cavities or holes and may have a flat top surface. Therefore, even if there are cavities or holes in the lower portion 134b of the conductor filler material 134, the flatter and greater top surface of the upper portion 134t of the conductor filler material 134 may still be in contact with the storage capacitor (not shown). Therefore, it is possible to maintain or even improve the electrical connection between the capacitive contact structure 108 and the storage capacitor while continuing to miniaturize the memory device 10.

In addition to covering the lower portion 134b of the conductor filler material 134, the upper portion 134t of the conductor filler material 134 may further be extended laterally to cover the top end of the sidewall portion of the barrier layer 132. Additionally, in some embodiments, the upper portion 134t of the conductor filler material 134 is also laterally in contact with the spacers 124 extended along the sidewalls of the bit line stack GC.

As further shown in FIG. 1B, the insulating filler material 136 may also be filled between adjacent capacitive contact structures 108. Although not shown, it should be understood that the insulating filler material 136 may laterally be in contact with the spacers 124 extended along the sidewalls of the bit line stack structure in addition to being laterally in contact with the capacitive contact structures 108. As an example, the insulating filler material 136 may include silicon nitride, silicon oxide (tetraethoxysilane (TEOS), spin on glass (SOG), the like, or a combination thereof) or a combination thereof.

As mentioned above, the conductive filler material 134 and the barrier layer 132 based on the capacitive contact structures 108 have special structures to ensure good electrical connection between the capacitive contact structures 108 and the storage capacitor.

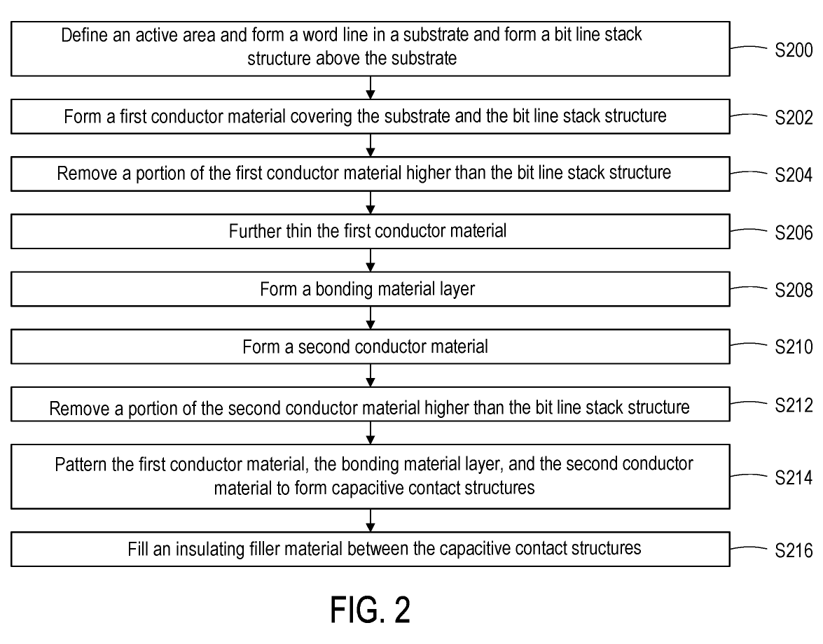

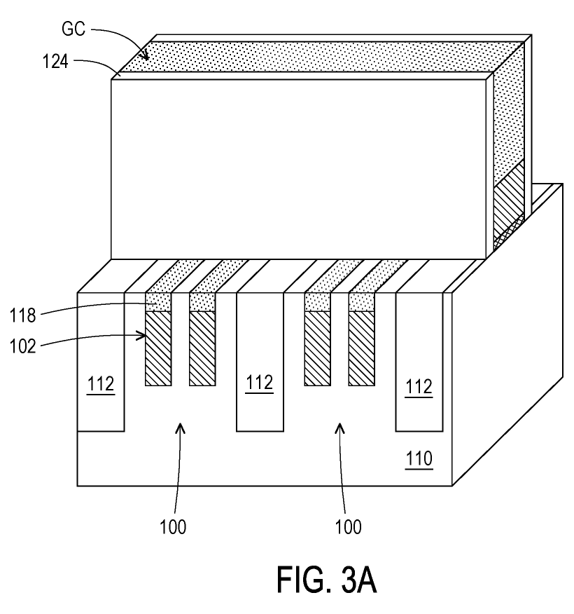

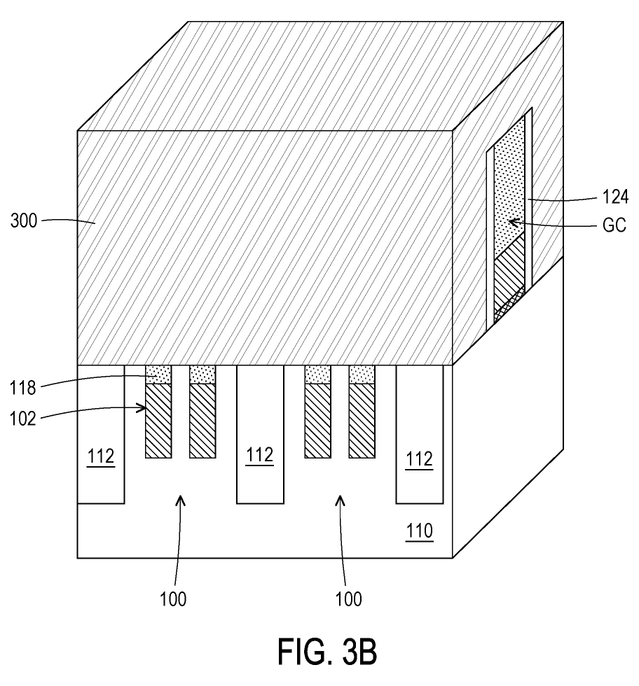

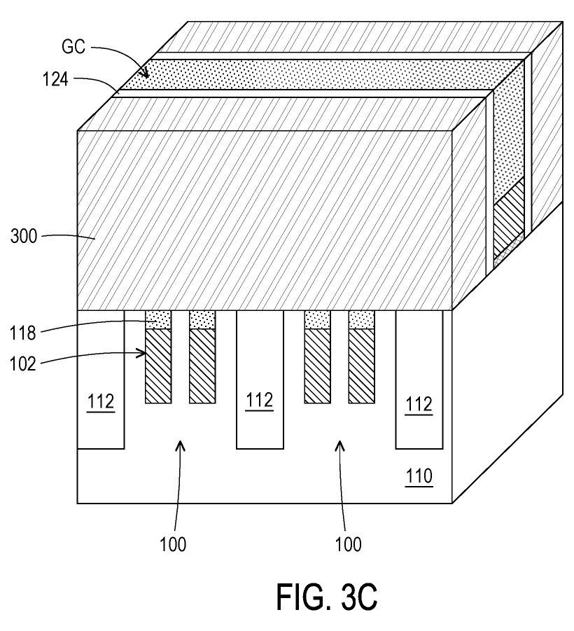

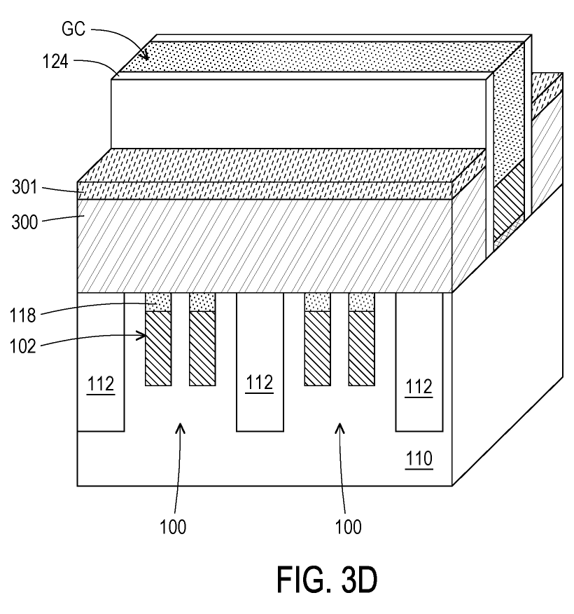

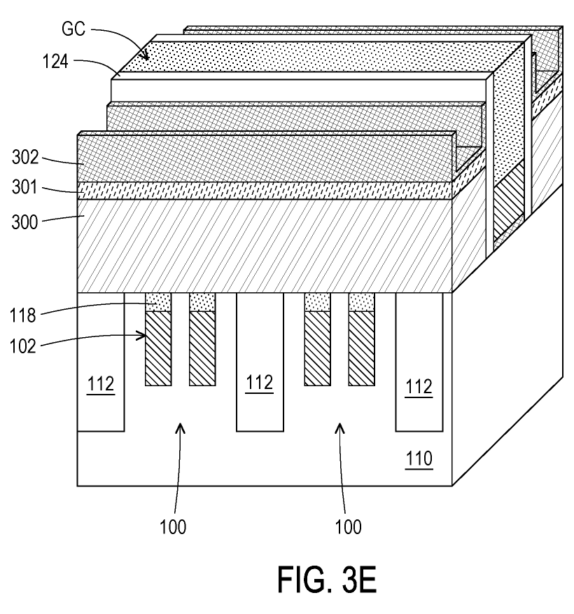

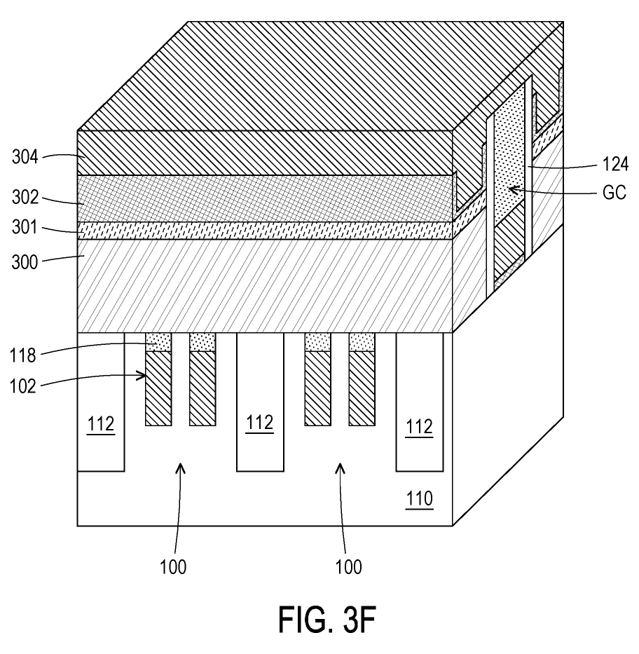

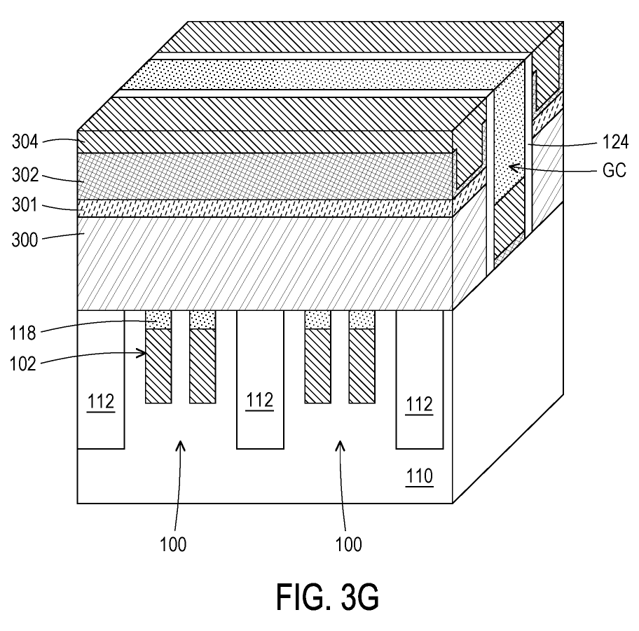

FIG. 2 is a flowchart of a method for forming the memory device 10 according to some embodiments. FIG. 3A to FIG. 3G are schematic three-dimensional views of a series of intermediate structures during the manufacturing process shown in FIG. 2.

Referring to FIG. 2 and FIG. 3A, in operation S200, the active areas 100 are defined and the word lines 102 are formed in the substrate 110, and the bit line stack structure GC is formed above the substrate 110. As described above, the active areas 100 may be defined by forming the isolation structures 112 in the substrate 110. In addition, the word lines 102 may be deeply buried in the substrate 110 and the word lines 102 are covered with the insulating plugs 118. Furthermore, a series of deposition processes may be performed and the deposited material layer may then be patterned to form the bit line stack structure GC. In some embodiments, the spacers 124 are further formed along the sidewalls of the bit line stack structure GC.

Referring to FIG. 2 and FIG. 3B, in operation S202, a first conductor material 300 covering the substrate 110 and the bit line stack structure GC is formed. In subsequent steps, the first conductor material 300 is patterned into the bottom contact structure 126 of the capacitive contact structures 108 described with reference to FIG. 1B to FIG. 1D. At the present stage, the first conductor material 300 is formed to a height greater than the bit line stack GC and completely covers the bit line stack structure GC.

Referring to FIG. 2 and FIG. 3C, at operation S204, a portion of the first conductor material 300 higher than the bit line stack structure GC is removed. In some embodiments, the first conductor material 300 is thinned via a planarization process. As an example, the planarization process described herein may include a grinding process, an etching process, or a combination thereof.

Referring to FIG. 2 and FIG. 3D, at operation S206, the first conductor material 300 is further thinned. As a result, the first conductor material 300 is recessed relative to the bit line stack structure GC. In some embodiments, the recessing of the first conductor material 300 is achieved via an etching process. In addition, in an embodiment in which the first conductor material 300 is formed by polycrystalline silicon, the surface layer portion of the first conductor material 300 may be further siliconized to form a metal silicide material layer 301. In a subsequent step, the metal silicide material layer 301 is patterned into the metal silicide layer 130 described with reference to FIG. 1B to FIG. 1D.

Referring to FIG. 2 and FIG. 3E, at operation S208, a bonding material layer 302 is formed. In a subsequent step, the bonding material layer 302 is patterned into the barrier layer 132 described with reference to FIG. 1B to FIG. 1D. At the current stage, the bonding material layer 302 is conformally extended along the bottom surface and the sidewalls of the recess defined by the first conductor material 300 (including the metal silicide material layer 301 of the surface layer portion) and the bit line stack structure GC. However, the topmost end of the bonding material layer 302 is not flush with the topmost end of the recess, but is slightly lower than the top surface of the bit line stack structure GC. In some embodiments, the forming of the bonding material layer 302 includes a conformal deposition process and an anisotropic etching process. As a result of the conformal deposition process, the bonding material layer 302 may completely cover the conductor material 300 (including the metal silicide material layer 301 of the surface portion) and the bit line stack structure GC. After the anisotropic etching process is performed, the portion of the bonding material layer 302 covering the top of the bit line stack structure GC is removed to form a recessed structure shown in FIG. 3E.

Referring to FIG. 2 and FIG. 3F, at operation S210, a second conductor material 304 is formed. In subsequent steps, the second conductor material 304 is patterned into the conductor filler material 134 of the capacitive contact structures 108 described with reference to FIG. 1B to FIG. 1D. At the current stage, the conductor material completely fills the recess defined by the bonding material layer 302 and is further formed to a height greater than the top surface of the bit line stack structure GC, so as to completely cover the bonding material layer 302 and the bit line stack structure GC.

Referring to FIG. 2 and FIG. 3G, at operation S212, a portion of the second conductor material 304 higher than the bit line stack structure GC is removed. As a result, the top surface of the bit line stack structure GC is exposed, and the top surface of the second conductor material 304 is substantially flush with the top surface of the bit line stack structure GC. In some embodiments, the second conductor material 304 is thinned via a planarization process.

Subsequently, at operation S214, the first conductor material 300 (including the metal silicide material layer 301 of the surface layer portion), the bonding material layer 302, and the second conductor material 304 are patterned. The patterning result is shown in FIG. 1D, forming the bottom contact structure 126 of a capacitive contact structure 108, the metal silicide layer 130, the barrier layer 132 of the top contact structure 128, and the conductor filler material 134 of the top contact structure 128. As a result of being patterned in the same step, the conductor filler material 134 and the barrier layer 132 of the top contact structure, the metal silicide layer 130, and the bottom contact structure 126 may have sidewalls that are substantially flush with each other.

Next, at operation S216, the insulating filler material 136 as shown in FIG. 1B may be filled between the capacitive contact structures 108. In addition, although not shown, a storage capacitor is subsequently formed on the capacitive contact structure 108 to form the complete memory device 10.

In some embodiments, the patterning operations described with reference to FIG. 3G and FIG. 1D are implemented using multiple patterning techniques.

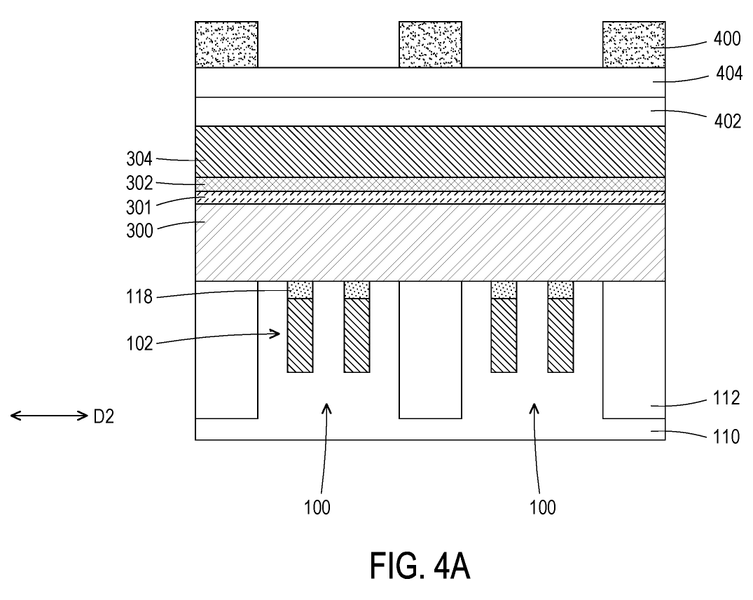

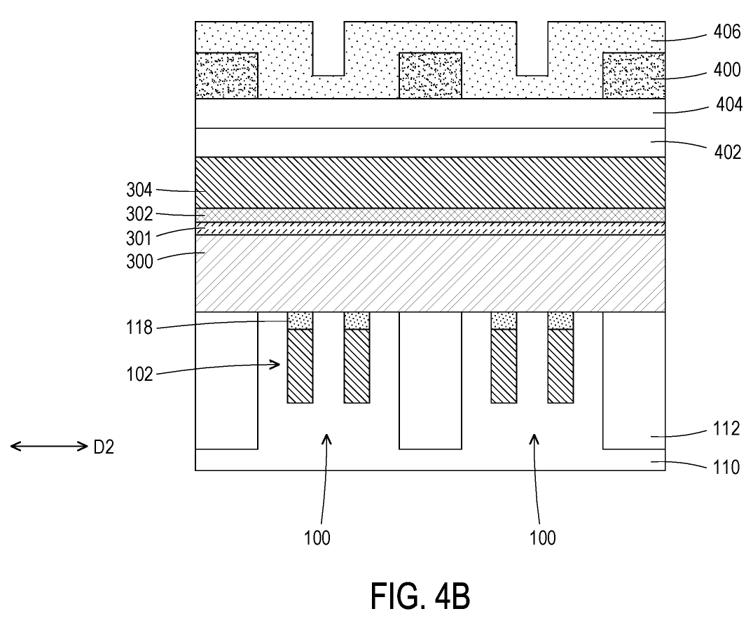

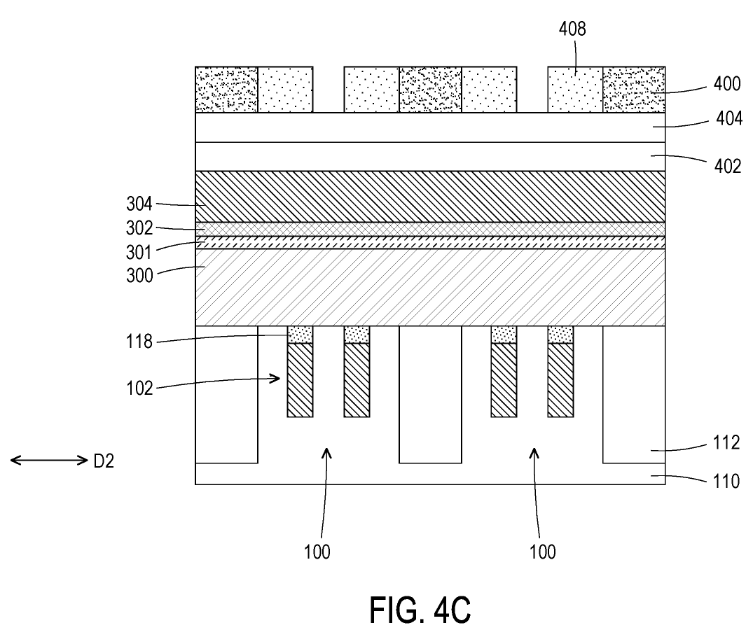

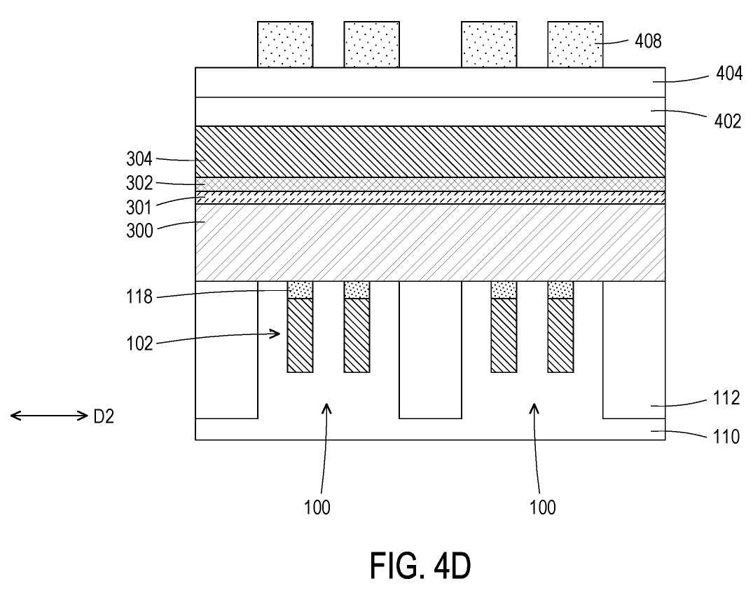

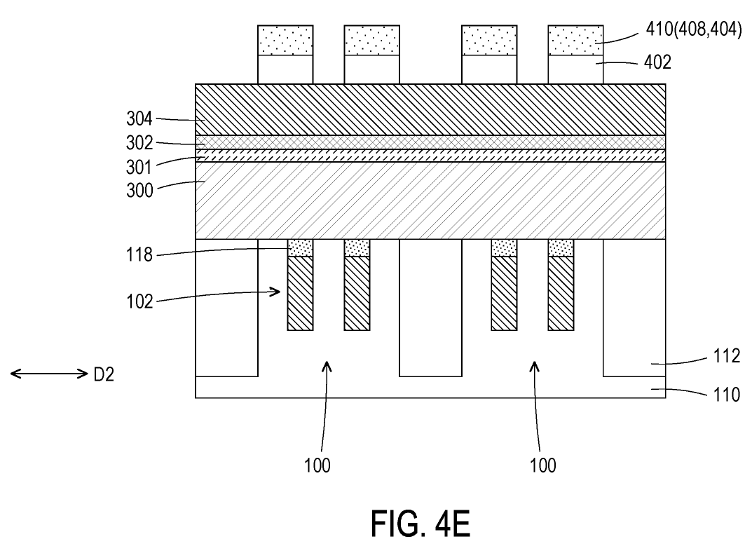

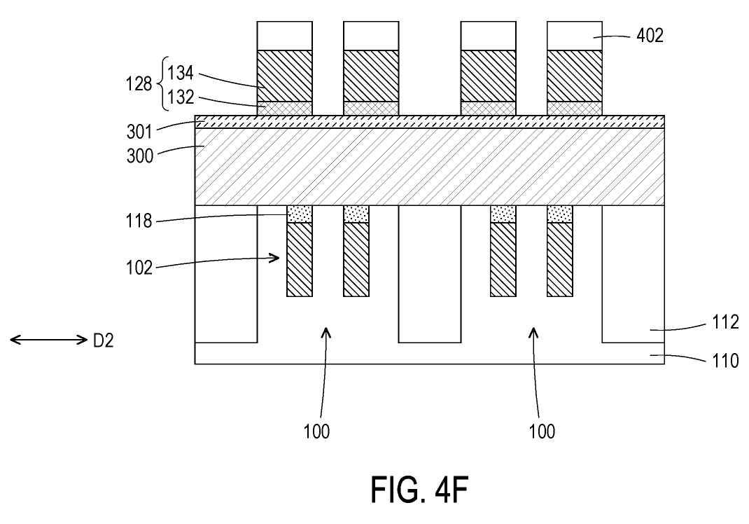

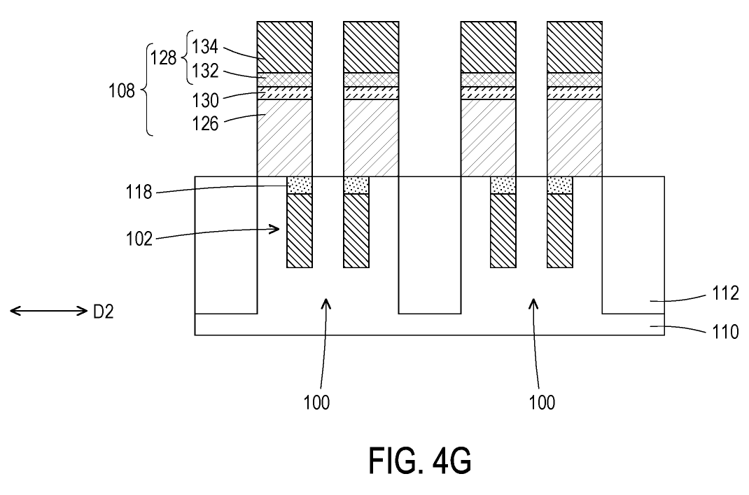

FIG. 4A to FIG. 4F show the patterning operation of the capacitive contact structures 108 using a schematic cross-sectional view in the second direction D2.

At the stage shown in FIG. 4A, a first mask pattern 400 formed by, for example, a photoresist, is formed on the conductor material 304. In some embodiments, before the first mask pattern 400 is formed, at least one functional layer 402 and a hard mask layer 404 are sequentially stacked on the conductor material 304.

At the stage shown in FIG. 4B, a second mask layer 406 is formed on the current structure. The second mask layer 406 conformally covers the first mask pattern 400 and the underlying structure thereof. In an embodiment in which the hard mask layer 404 is formed below the first mask pattern 400, the second mask layer 406 is extended conformally along the surfaces of the first mask pattern 400 and the hard mask layer 404.

At the stage shown in FIG. 4C, an anisotropic etching operation is performed. As a result, the horizontally extending portion of the second mask layer 406 is removed, leaving a second mask pattern 408 extended longitudinally along the sidewalls of the first mask pattern 400. Since this patterning operation does not involve a photolithography operation, this patterning operation is also called a self-aligned patterning operation. In addition, since the second mask patterns 408 are positioned between the first mask patterns 400, the pitch of the second mask patterns 408 may be shorter than the pitch of the first mask patterns 400. When the pitch of the first mask patterns 400 approaches the process limit, the pitch of the second mask patterns 408 may exceed the process limit.

At the stage shown in FIG. 4D, the first mask patterns 400 are removed by any suitable process, leaving the second mask patterns 408. At this point, the first mask patterns 400 having a greater pitch is transferred to the second mask patterns 408 having a shorter pitch.

At the stage shown in FIG. 4E, an etching operation is performed using the second mask patterns 408. In some embodiments, portions of the hard mask layer 404 and the functional layer 402 not obscured by the second mask patterns 408 are removed, and portions overlapped with the second mask patterns 408 remain. In some examples, the second mask patterns 408 and the hard mask layer 404 are formed by the same material, and the two layers may be collectively referred to as a second mask 410.

At the stage shown in FIG. 4F, an etching operation is performed using the second mask 410 and the patterned functional layer 402. As a result, the conductive material 304 and the boning material layer 302 are patterned into the conductive filler material 134 and the barrier layer 132 of the top contact structure 128 of the capacitive contact structures 108. At this time, the second mask 410 may be thinned or consumed to expose the functional layer 402.

Lastly, at the stage shown in FIG. 4G, an etching operation is performed using the remaining mask (such as the functional layer 402) and the underlying conductor filler material 134 and the barrier layer 132 to pattern the metal silicide material layer 301 into the metal silicide layer 130, and the conductor material 300 is patterned into the bottom contact structure 126 of the capacitive contact structures 108. If the mask is not exhausted at this time, a suitable process may be performed to remove the remaining mask (e.g., the functional layer 402).

It should be understood that in addition to the dual patterning operation described above, any other suitable patterning operation may also be used to pattern the capacitive contact structures 108. The invention is not limited thereto.

Based on the above, the disclosure provides a memory device and a forming method thereof. In each cell of the memory device, the capacitive contact structure used to connect the access transistor and the storage capacitor has the bottom contact structure and the top contact structure. In particular, the top contact structure has the recessed barrier layer and the recess filled in the barrier layer and further formed with the conductor filler material higher than the topmost end of the barrier layer. The lower portion of the conductor filler material may develop cavities or holes during the forming process due to being confined within the recess of the barrier layer. Nonetheless, the upper portion of the conductor filler material is not limited to the recess of the barrier layer and has a greater area, making it less likely to form cavities or holes. In this way, the upper portion of the conductor filler material may have a greater and flatter surface. Therefore, even if there are cavities or holes in the lower portion of the conductor filler material, the flatter and greater top surface of the upper portion of the conductor filler material may still be in contact with the storage capacitor. Therefore, it is possible to maintain or even improve the electrical connection between the capacitive contact structure and the storage capacitor while continuing to miniaturize the memory device.

What is claimed is:

1. A memory device, comprising:
an access transistor;
a capacitive contact structure configured to connect a drain/source of the access transistor to an overlying storage capacitor, and comprising:
a bottom contact structure; and
a top contact structure disposed above the bottom contact structure and comprising a barrier layer and a conductor filler material connected to the bottom contact structure via the barrier layer, wherein the barrier layer is extended along a bottom surface and two opposite sidewalls of the conductor filler material, a lower portion of the conductor filler material is filled in a recess defined by the barrier layer, and an upper portion of the conductor filler material is higher than a topmost end of the barrier layer and has a greater width relative to the lower portion; and
a bit line stack structure adjacent to the capacitive contact structure and having a bit line connected to another drain/source of the access transistor.

2. The memory device of claim 1, wherein the barrier layer does not completely surround the lower portion of the conductor filler material.

3. The memory device of claim 1, wherein the barrier layer covers the two opposite sidewalls of the conductor filler material but does not cover other sidewalls of the conductor filler material.

4. The memory device of claim 1, wherein the barrier layer only covers two opposite sidewalls of the lower portion of the conductor filler material parallel to the bit line stack structure, and does not cover other two sidewalls of the lower portion of the conductor filler material perpendicular to the bit line stack structure.

5. The memory device of claim 1, wherein the upper portion of the conductor filler material covers the topmost portion of the barrier layer.

6. The memory device of claim 1, wherein sidewalls of the conductor filler material are substantially coplanar with sidewalls of the barrier layer and sidewalls of the bottom contact structure.

7. The memory device of claim 1, further comprising:
a spacer extended between the bit line stack structure and the capacitive contact structure.

8. The memory device of claim 7, wherein the upper portion of the conductor filler material is laterally in contact with the spacer.

9. The memory device of claim 1, wherein a top surface of the conductor filler material is substantially flush with a top surface of the bit line stack structure, and the topmost end of the barrier layer is lower than the top surface of the bit line stack structure.

10. The memory device of claim 1, wherein the capacitive contact structure further comprises a metal silicide layer extended between the bottom contact structure and the top contact structure.

11. The memory device of claim 1, wherein the conductor filler material comprises tungsten, and the barrier layer comprises titanium and titanium nitride.

12. The memory device of claim 1, wherein the bottom contact structure comprises polysilicon.

13. The memory device of claim 1, wherein the bit line stack structure further comprises a bit line contact structure extended below the bit line.

14. A method of forming a memory device, comprising:
forming a plurality of access transistors in a substrate;
forming a bit line stack structure on the substrate, wherein the bit line stack structure crosses over a plurality in the plurality of access transistors; and
forming a plurality of capacitive contact structures on the substrate along two sides of the bit line stack structure, wherein the plurality of capacitive contact structures respectively comprise:
a bottom contact structure; and
a top contact structure disposed above the bottom contact structure and comprising a barrier layer and a conductor filler material connected to the bottom contact structure via the barrier layer, wherein the barrier layer is extended along a bottom surface and two opposite sidewalls of the conductor filler material, a lower portion of the conductor filler material is filled in a recess defined by the barrier layer, and an upper portion of the conductor filler material is higher than a topmost end of the barrier layer and has a greater width relative to the lower portion.

15. The method of forming the memory device of claim 14, wherein forming the plurality of capacitive contact structures comprises:
forming a first conductor material adjacently connected to the bit line stack structure on the substrate, wherein a top surface of the first conductor material is lower than a top surface of the bit line stack structure;
forming a bonding material layer on the first conductor material, wherein the bonding material layer is conformally extended along the top surface of the first conductor material and a sidewall of the bit line stack structure;
forming a second conductor material on the bonding material layer, wherein a top surface of the second conductor material is higher than a topmost end of the bonding material layer and substantially flush with the top surface of the bit line stack structure; and
performing a patterning operation to pattern the second conductor material into a plurality of top contact structures of the plurality of capacitive contact structures, pattern the bonding material layer into a plurality of barrier layers of the plurality of capacitive contact structures, and pattern the first conductor material into a plurality of bottom contact structures of the plurality of capacitive contact structures.

16. The method of forming the memory device of claim 15, wherein forming the bonding material layer comprises performing a conformal deposition operation, and comprises performing an anisotropic etching operation such that the topmost end of the bonding material layer is lower than the top surface of the bit line stack structure.

17. The method of forming the memory device of claim 15, wherein the patterning operation is a dual patterning operation.

18. The method of forming the memory device of claim 15, wherein the plurality of capacitive contact structures further comprise a metal silicide layer extended between the bottom contact structure and the top contact structure, forming the plurality of capacitive contact structures comprises converting a surface layer of the first conductor into a metal silicide material layer before the bonding material layer is formed, and patterning the metal silicide material layer into a plurality of metal silicide layers during the patterning operation.

19. The method of forming the memory device of claim 14, further comprising forming a spacer extended between the bit line stack structure and the plurality of capacitive contact structures.
